(19) United States
(12) Patent Application Publication
(10) Pub. No.: US 2015/0001700 A1
(43) Pub. Date: Jan. 1, 2015

(54) Power Modules with Parylene Coating

(71) Applicant: Infineon Technologies AG, Neubiberg (DE)

(72) Inventors: Hans Hartung, Warstein (DE); Johannes Uhlig, Soest (DE); Christian Domesle, Warstein (DE)

(21) Appl. No.: 13/930,607

(22) Filed: Jun. 28, 2013

(51) Int. Cl. H01L 23/00; H01L 23/29; H01L 21/56

(52) U.S. Cl. CPC H01L 23/564; H01L 21/56; H01L 23/293
USPC 257/698; 438/126

(57) ABSTRACT

A module includes a base plate, a substrate having a first metallized side attached to the base plate and an opposing second metallized side, a power semiconductor die attached to the second metallized side of the substrate at a first side of the die, a first plurality of electrical connections between the second metallized side of the substrate and a second side of the die opposing the first side of the die, and a housing attached to a periphery of the base plate. The housing and base plate enclose the die and the first electrical connections. A second plurality of electrical connections extend from the second metallized side of the substrate through the housing to provide external electrical connections for the module. A parylene coating prevents gases and humidity from reaching the die, the first electrical connections, and the first metallized side of the substrate.

### FIELD OF TECHNOLOGY

The present application relates to power modules, in particular humidity-resistant power modules.

### BACKGROUND

Modules for power semiconductor dies typically exhibit vapor diffusion due to the polymer materials conventionally used for mechanical and chemical protection, as well as electrical insulation of the module. Ion impurities and ion diffusion result in the presence of electrolytes on the die surfaces, which, in combination with higher temperature and voltage, lead to corrosion effects on the semiconductor dies. These processes eventually result in failure of the module.

Materials sensitive to corrosion, electrochemical migration, and dendritic growth include aluminum, copper, and silver. Standard insulation materials used in power modules are based on silicones, since silicones are prone to chemicals and elevated temperatures and also show good dielectric strength. Although water uptake of silicone is relatively low, silicones do not shield underlying materials from vapor diffusion. This is a result of the high free volume in the polymer due to the high flexibility of the siloxane backbone.

The application of additional layers of solvent-based vapor barriers such as lacquer, conformal coatings, etc. on the surface of the module is difficult because of the complex structures that prevent uniform coatings. Materials with low elasticity are problematic because of the mechanical stress exerted on wire bonds and other types of interconnects employed within the module. High operating temperatures of 150° C. and greater in power modules also prevent the application of many standard coating materials such as urethane and epoxy.

### SUMMARY

According to an embodiment of a module, the module comprises a base plate, a substrate having a first metallized side attached to the base plate and an opposing second metallized side, a power semiconductor die attached to the second metallized side of the substrate at a first side of the die, a first plurality of electrical connections between the second metallized side of the substrate and a second side of the die opposing the first side of the die, a housing attached to a periphery of the base plate so that the die and the first plurality of electrical connections are enclosed by the housing and the base plate, and a second plurality of electrical connections extending from the second metallized side of the substrate through the housing to provide external electrical connections for the module. The module further comprises a parylene coating which prevents gases and humidity from reaching the die, the first plurality of electrical connections and the first metallized side of the substrate.

According to an embodiment of a method of manufacturing a humidity-resistant power semiconductor module, the method comprises: providing a module comprising a base plate, a substrate having a first metallized side attached to the base plate and an opposing second metallized side, a power semiconductor die attached to the second metallized side of the substrate at a first side of the die, a first plurality of electrical connections between the second metallized side of the substrate and a second side of the die opposing the first side of the die, a housing attached to a periphery of the base plate so that the die and the first plurality of electrical connections are enclosed by the housing and the base plate, and a second plurality of electrical connections extending from the second metallized side of the substrate through the housing to provide external electrical connections for the module; and applying a parylene coating to the module that prevents gases and humidity from reaching the die, the first plurality of electrical connections, and the second metallized side of the substrate.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of an embodiment of a power semiconductor module with a parylene coating.

FIG. 2 illustrates a cross-sectional view of another embodiment of a power semiconductor module with a parylene coating.

FIG. 3 illustrates a cross-sectional view of yet another embodiment of a power semiconductor module with a parylene coating.

FIGS. 4A through 4C illustrate respective cross-sectional views of power semiconductor modules just prior to parylene deposition.

FIG. 5 illustrates a diagram of an embodiment of a method of coating a power semiconductor module with parylene.

### DETAILED DESCRIPTION

The embodiments described herein provide a power semiconductor module with a parylene coating. The parylene coating prevents gases and humidity from reaching corrosion-sensitive components inside the module.

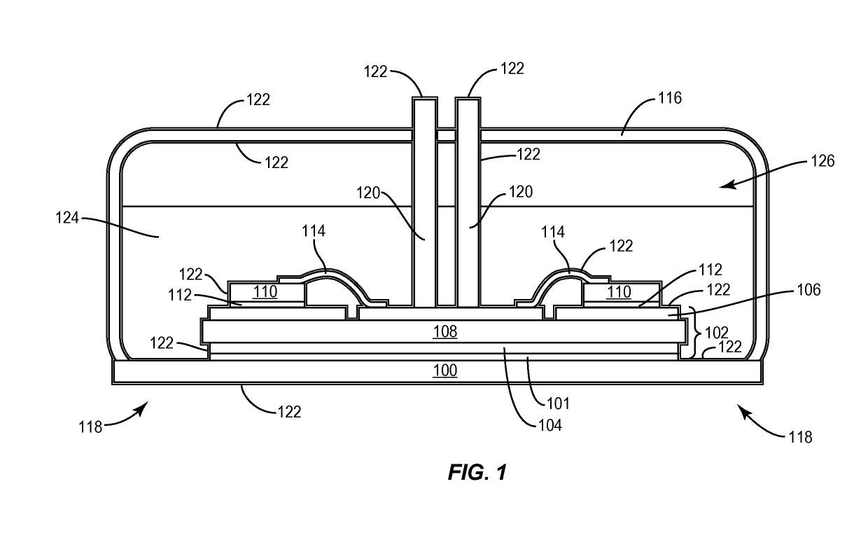

FIG. 1 illustrates a cross-sectional view of an embodiment of a power semiconductor module having a parylene coating. The module includes a base plate 100 and a substrate 102. The substrate 102 has a bottom metallized side 104 attached to the base plate 100, e.g., via solder 101, and an opposing top metallized side 106. The base plate 100 is thermally conductive. The base plate 100 can be electrically conductive or insulative. For example, the base plate 100 can be a metal block or a ceramic such as AIN.

The substrate 102 comprises an isolation material 108 with opposing metallized sides 104, 106. The metallized top side 106 of the substrate 102 can comprise the same or different material as the metallized bottom side 104 of the substrate 102. For example, the substrate 102 can be a standard DCB (direct copper bonded), DAB (direct aluminum bonded), AMB (active metal brazed) or IMS (insulated metal substrate) substrate. A standard DCB substrate includes copper surfaces 104, 106 applied to the top and bottom areas of an isolation material 108 such as Al₂O₃ ceramic material. A standard DAB substrate includes aluminum surfaces 104, 106 applied to the top and bottom areas of a ceramic material 108. A standard AMB substrate includes metal foils 104, 106 brazed to opposing sides of an isolation material 108 such as an AIN ceramic material. A standard IMS substrate includes an isolation material 108 such as a polymer directly connected to the base plate 100. In each case, the metallized top side 106 of the substrate 102 can be patterned so that more than one power semiconductor dies 110 can be attached to the metallized top side 106 of the substrate 102.

At least one of the power semiconductor dies 110 has a maximum operating temperature of 150° C. to 175° C. or higher and a maximum operating power of 200W to 24 kW or higher. Each power semiconductor die 110 is attached to the metallized top side 106 of the substrate 102 at a bottom side of the respective dies 110 via solder 112. The dies 110 can be any type of power semiconductor die such as power transistor and/or power diode dies fabricated in any type of semiconductor technology such as Si, SiC, GaAs, GaN, etc. A first plurality of electrical connections 114, such as copper or aluminum wire bonds, ribbons, clips, etc., connect the metallized top side 106 of the substrate 102 to one or more terminals disposed at the (top) side of the dies 110 which faces away from the substrate 102. The die terminals are not shown for ease of illustration.

The module further includes a housing 116 attached to a periphery 118 of the base plate 100. The housing 116 covers or protects the components within the module such as the die(s) 110, the first plurality of electrical connections 114 and the substrate 102. The housing 116 is not air-tight, and therefore gases and humidity can penetrate the lid 116. The housing 116 can be formed by injection molding or other suitable process, and glued to the periphery 118 of the base plate 102. In one embodiment, the housing 116 is a polymer lid. The housing 116 and the base plate 100 together form an enclosure that encloses the die(s) 110 and the first plurality of electrical connections 114. A second plurality of electrical connections 120, such as pins or posts extend from the metallized top side 106 of the substrate 102 through the housing 116 to provide external electrical connections for the module, e.g., such as power, input signals, output signals, etc.

A parylene coating 122 is applied to the module. Parylene is the generic name for a variety of chemical vapor deposited poly(p-xylylene) polymers. Parylene has excellent barrier properties, low water uptake, good dielectric strength, and high chemical resistance. Parylene is essentially free of ionic contaminants due to its deposition from a vapor phase. Since corrosion processes depend on the presence of both ions and humidity on metal surfaces, the parylene coating 122 effectively slows down water diffusion and therefore inhibits or at least reduces corrosion of the sensitive components inside the module. This includes ion impurity-based corrosion effects and sulfide dendrite growth, since hydrogen sulfide chemistry with metals is promoted by humidity. Low water uptake by the parylene coating 122 avoids, or at least reduces, the presence of critical water concentrations near each surface protected by the parylene coating 122. The parylene coating 122 has good adhesion and uniformity, which additionally lowers the presence of surface electrolytes, even on complex and delicate structures of the power semiconductor module. In one embodiment, the parylene coating 122 is partly fluorinated. For example, the parylene coating 122 can be commercially available partly fluorinated parylene where hydrogen is substituted by fluorine atoms either on the aromatic ring or the aliphatic bridge atoms (e.g. parylene AF-4 or VT-4, also referred to as parylene F, parylene HT, parylene SF, etc.). These fluorinated parylenes remain stable at elevated temperatures of at least 350° C.

Due to the gas phase deposition of parylene, the parylene coating 122 covers the exterior surface of the housing 116 and base plate 100 and penetrates the permeable lid 116, coating the exposed (uncovered or unmasked) components inside the module. Parylene is a highly conformal material, and therefore the parylene coating 122 provides a generally uniform coating on the corrosion-sensitive components within the module, such as the die(s) 110, the first plurality of electrical connections 114, and the metallized top side 106 of the substrate 102. The parylene coating 122 prevents gases and humidity from reaching the sensitive components within the module.

The module further includes a potting compound 124 such as silicone or other polymer-based potting compound suitable for high power semiconductor applications. The potting compound 124 fills at least part of a void 126 in the module between the housing 116 and the base plate 100. According to the embodiment shown in FIG. 1, the void 126 in the module is at least partly filled with the potting compound 124 after the parylene coating 122 is applied to the module. As such, the parylene coating 122 is applied directly to the metallized top side 106 of the substrate 102, the first plurality of electrical connections 114, the die(s) 110, and the exterior surface of the housing 116. In one embodiment, a primer is applied to the substrate 102 and the die(s) 110 before application of the parylene coating 122. The primer is an adhesion promoter, and can also be a cleaning agent. For example, the primer can be a silicon compound such as silane. The primer is relatively thin, and therefore not visible in FIG. 1. The primer increases the adhesion with the subsequently applied parylene coating 122. In this embodiment, the parylene coating 122 is applied to the primer, the first plurality of electrical connections 114 and the exterior surface of the housing 116, and then the module void 126 is filled with the potting compound 124.

The surface of the module can be activated before the void 126 is at least partly filled by the potting compound 124 to increase the adhesion between the parylene coating 122 and the potting compound 124. In one embodiment, the surface of the module is activated before potting by exposing the module to an oxygen plasma. The oxygen plasma increases the polarity of the module surface (including the parylene coating 122), allowing the potting compound 124 to better adhere to the underlying parylene coating 122.

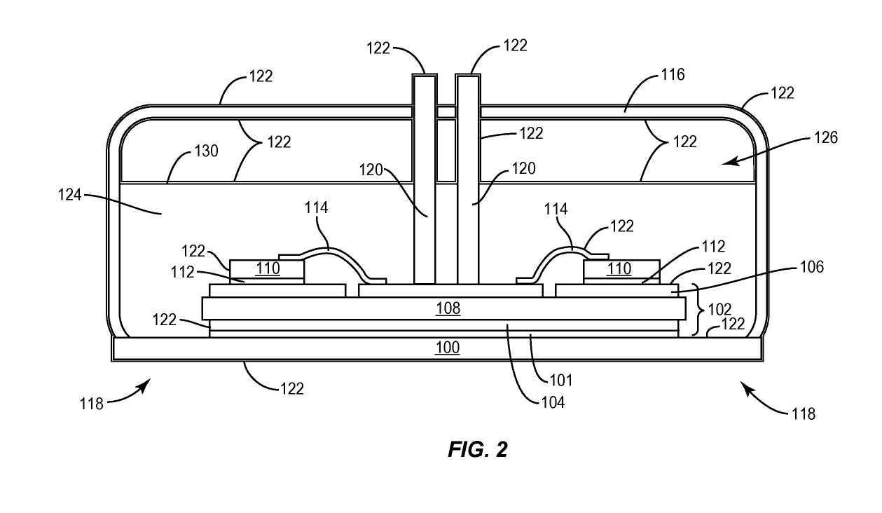

FIG. 2 illustrates a cross-sectional view of another embodiment of a power semiconductor module having a parylene coating. The module shown in FIG. 2 is similar to the one shown in FIG. 1, however, the module is potted before the parylene coating 122 is applied to the module. According to this embodiment, the parylene coating 122 is applied to the surface 130 of the potting compound 124 facing away from the base plate 100 and the exterior surface of the housing 116. As such, the parylene coating 122 is not in direct contact with the substrate 102, the first plurality of electrical connections 114 and the die(s) 110.

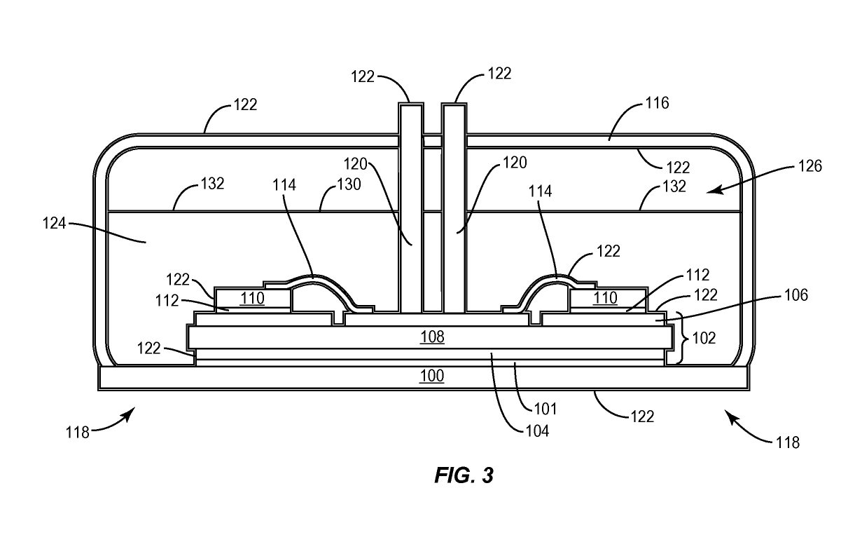

FIG. 3 illustrates a cross-sectional view of yet another embodiment of a power semiconductor module having a parylene coating. The module shown in FIG. 3 is similar to the one shown in FIGS. 1 and 2, however, the module is coated with parylene before and after potting. A first parylene coating 122 is applied to the module before the potting compound 124 is introduced into the module void 126. A second parylene coating 132 is applied to the module after the potting compound 124 is cured. According to this embodiment, parylene 122, 132 coats the substrate 102, the first plurality of electrical connections 114, the power die(s) 110, the surface 130 of the potting compound 124 facing away from the base plate 100, and the exterior surface of the housing 116 and base plate 102.

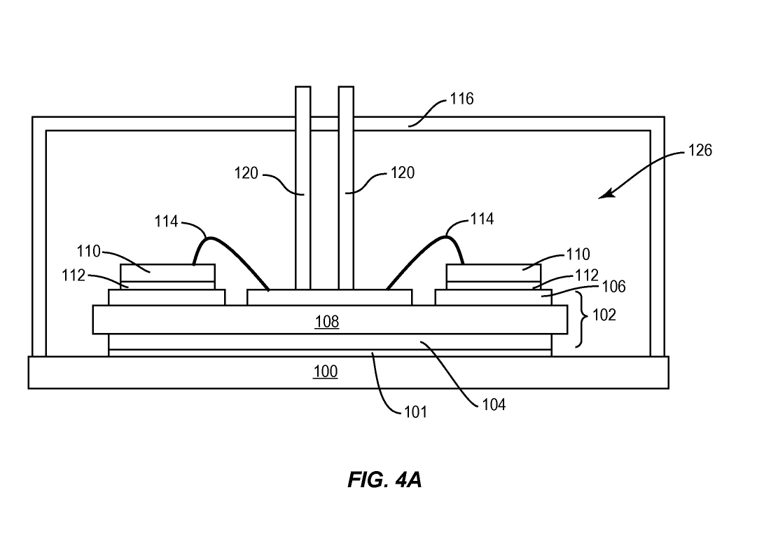

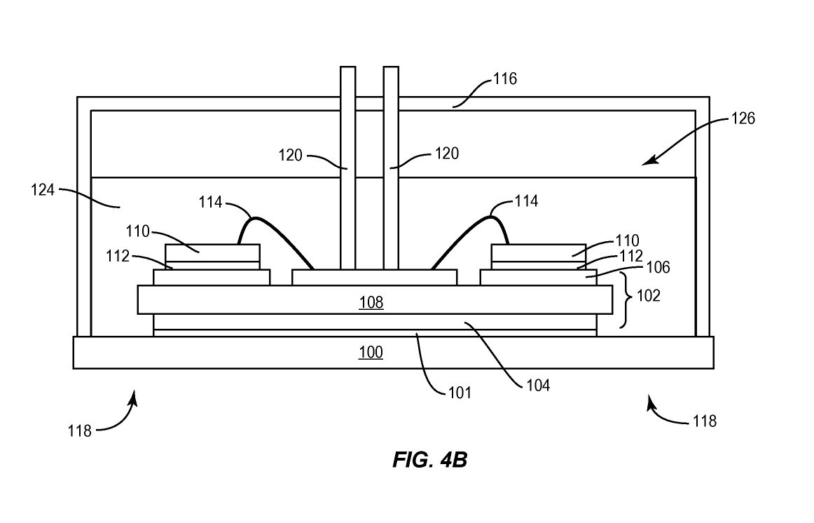

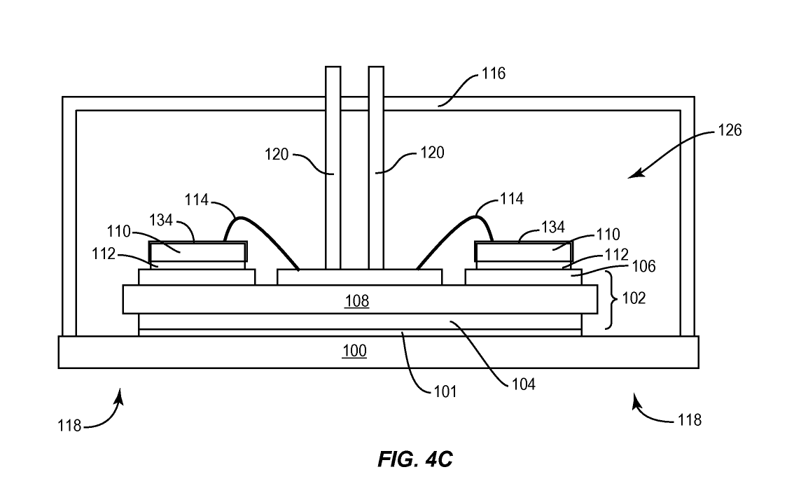

FIGS. 4A through 4C illustrate cross-sectional views of different embodiments of the power semiconductor module just prior to entering a deposition chamber for parylene coating. In FIG. 4A, the module is placed in the deposition chamber before potting compound. In FIG. 4B, the module is placed in the deposition chamber after potting. In FIG. 4C, an additional parylene coating 134 is applied only to the power semiconductor die(s) 110 before the module is placed in the deposition chamber. The die(s) 110 may be coated with parylene 134 at the die fabrication site or afterward. In each case, the module can be potted before or after the initial parylene deposition.

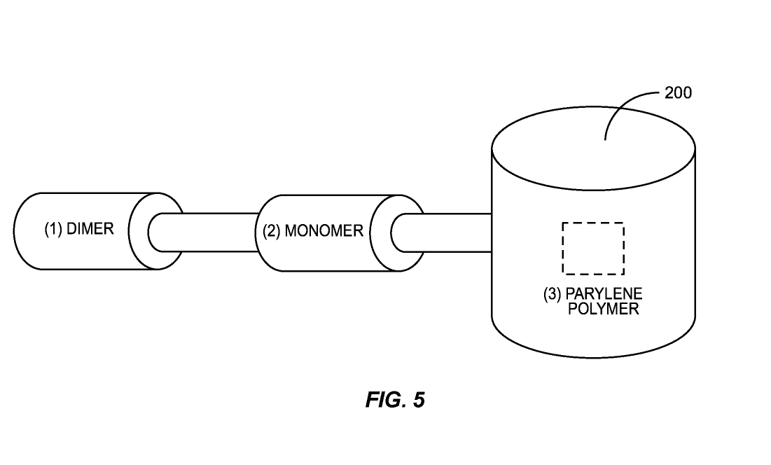

FIG. 5 illustrates an embodiment of a method of manufacturing the humidity-resistant power semiconductor module previously described herein. The module is placed in a deposition chamber 200. The module is represented by a dashed box in FIG. 5, and can be potted before or after the first parylene deposition. The module can be coated with parylene one or more times, e.g., before and/or after potting. A primer can be applied to the substrate 102 and the die(s) 110, e.g., by an oxygen plasma, before the module is first coated with parylene. The surface of the module can be activated before potting and parylene deposition to increase the adhesion between the parylene coating 122 and the potting compound 124.

In each case, the parylene deposition process includes vaporizing a solid dimer at a first elevated temperature, e.g., at about 150° C. and 1.0 torr (Step 1). The dimer is then decomposed by pyrolysis at a second elevated temperature greater than the first elevated temperature in the absence of oxygen to yield monomeric para-xylylene e.g. at about 680° C. and 0.5 torr (Step 2). The monomeric para-xylylene is then injected into the deposition chamber 200 that includes the module at a temperature lower than the first and second elevated temperatures so that the monomeric para-xylylene polymerizes on the module, e.g., at about 25° C. and 0.1 torr (Step 3). Other parylene deposition processes can be used to coat the power semiconductor module with parylene.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A module, comprising:
a base plate;
a substrate having a first metallized side attached to the base plate and an opposing second metallized side;
a power semiconductor die attached to the second metallized side of the substrate at a first side of the die;
a first plurality of electrical connections between the second metallized side of the substrate and a second side of the die opposing the first side of the die;
a housing attached to a periphery of the base plate so that the die and the first plurality of electrical connections are enclosed by the housing and the base plate;
a second plurality of electrical connections extending from the second metallized side of the substrate through the housing to provide external electrical connections for the module; and
a parylene coating which prevents gases and humidity from reaching the die, the first plurality of electrical connections and the first metallized side of the substrate.

2. The module of claim 1, further comprising a potting compound filling at least part of a void in the module between the housing and the base plate.

3. The module of claim 2, wherein the parylene coating is applied to a surface of the potting compound facing away from the base plate and an exterior surface of the housing so that the parylene coating does not contact the substrate, the first plurality of electrical connections and the die.

4. The module of claim 2, wherein the parylene coating is applied to a surface of the potting compound facing away from the base plate, the module further comprising an additional parylene coating applied to the substrate, the first plurality of electrical connections and the die.

5. The module of claim 2, wherein the potting compound comprises silicone.

6. The module of claim 1, wherein the parylene coating is applied directly to the second metallized side of the substrate, the first plurality of electrical connections, the die and an exterior surface of the housing.

7. The module of claim 1, further comprising an additional parylene coating applied only to the die.

8. The module of claim 1, wherein the first plurality of electrical connections are copper bond wires.

9. The module of claim 1, wherein the parylene coating is partly fluorinated.

10. The module of claim 1, further comprising a primer applied to the substrate and the die, and wherein the parylene coating is applied to the primer, the first plurality of electrical connections and an exterior surface of the housing.

11. The module of claim 1, wherein the substrate comprises a ceramic with a sheet of copper bonded to each of opposing first and second sides of the ceramic.

12. A method of manufacturing a humidity-resistant power semiconductor module, the method comprising:
providing a module comprising a base plate, a substrate having a first metallized side attached to the base plate and an opposing second metallized side, a power semiconductor die attached to the second metallized side of the substrate at a first side of the die, a first plurality of electrical connections between the second metallized side of the substrate and a second side of the die opposing the first side of the die, a housing attached to a periphery of the base plate so that the die and the first plurality of electrical connections are enclosed by the housing and the base plate, and a second plurality of electrical connections extending from the second metallized side of the substrate through the housing to provide external electrical connections for the module; and
applying a parylene coating to the module that prevents gases and humidity from reaching the die, the first plurality of electrical connections and the second metallized side of the substrate.

13. The method of claim 12, further comprising filling at least part of a void in the module between the housing and the base plate with a potting compound.

14. The method of claim 13, wherein the parylene coating is applied to the module after the void is at least partly filled by the potting compound so that the parylene coating is applied to a surface of the potting compound facing away from the base plate and an exterior surface of the housing and the parylene coating does not contact the substrate, the first plurality of electrical connections and the die.

15. The method of claim 13, wherein the parylene coating is applied to the module after the void is at least partly filled by the potting compound so that the parylene coating is applied to a surface of the potting compound facing away from the base plate, the method further comprising:
applying an additional parylene coating to the substrate, the first plurality of electrical connections and the die before the void is at least partly filled by the potting compound.

16. The method of claim 13, wherein the parylene coating is applied to the module before the void is at least partly filled by the potting compound, the method further comprising:
activating a surface of the module before the void is at least partly filled by the potting compound to increase the adhesion between the parylene coating and the potting compound.

17. The method of claim 16, wherein activating the surface of the module before the void is at least partly filled by the potting compound comprises exposing the module to an oxygen plasma.

18. The method of claim 12, wherein the parylene coating is applied directly to the second metallized side of the substrate, the first plurality of electrical connections, the die and an exterior surface of the housing.

19. The method of claim 12, further comprising applying a primer to the substrate and the die, and wherein the parylene coating is applied to the module after the primer is applied.

20. The method of claim 12, wherein applying a parylene coating to the module comprises:
vaporizing a solid dimer at a first elevated temperature;
decomposing the dimer at a second elevated temperature greater than the first elevated temperature in the absence of oxygen to yield monomeric para-xylylene; and
injecting the monomeric para-xylylene into a deposition chamber that includes the module at a temperature lower than the first and second elevated temperatures so that the monomeric para-xylylene polymerizes on the module.
